(19) United States
(12) Patent Application Publication
(10) Pub. No.: US 2004/0005410 A1
(43) Pub. Date: Jan. 8, 2004

(54) Process for internally coating gas turbine blades or vanes and internally coated gas turbine blade or vane produced thereby

(75) Inventor: Frank Seidel, Isernhagen H.B. (DE)

Correspondence Address: CROWELL & MORING LLP, INTELLECTUAL PROPERTY GROUP, P.O. BOX 14300, WASHINGTON, DC, 20044-4300, US

(73) Assignee: MTU Aero Engines GmbH, Muenchen (DE)

(21) Appl. No.: 10/452,906

(22) Filed: Jun. 3, 2003

(30) Foreign Application Priority Data
Jun. 4, 2002 (DE) 102 24 632.7

(51) Int. Cl. B05D 7/22; C23C 16/00

(52) U.S. Cl. 427/255.28; 427/237

(57) ABSTRACT

A process for internally coating gas turbine blades or vanes with protective diffusion layers by way of a CVD process in a coating space at elevated temperature uses a process gas, a halide as activator, and a metallic material as donor for generating coating gas in the coating space. At a coating temperature, the pressure in the coating space is reduced by gas being sucked out. This is followed by refilling, at increasing pressure, with halide gas in order to immediately reform coating gas with the donor material.

This application claims the priority of German application 102 24 632.7, filed Jun. 4, 2002, the disclosure of which is expressly incorporated by reference herein.

### BACKGROUND AND SUMMARY OF THE INVENTION

The present invention relates to a process for internally coating gas turbine blades or vanes, with or without simultaneous external coating, with protective diffusion layers by a CVD process in a coating space, which can be sealed off from the environment, at elevated temperature using at least one of an inert process gas and a reactive process gas, at least one halide as an activator, and at least one metallic material as a donor. The activator and the donor are provided in the coating space in order to generate coating gas.

It is known to coat components of gas turbines in order to achieve functional improvements, such as protection against wear, corrosion, hot-gas corrosion, to reduce the heat transfer, and for other purposes.

Both with aircraft gas turbines and with stationary turbines, high operating temperatures, in particular in the turbine region, require measures for reducing oxidation and hot-gas corrosion; by way of example, aluminide protective layers are particularly effective against oxidation, and, by way of example, chromized protective layers are particularly effective against corrosion.

The layers are deposited on the components in diffusion processes from the vapor phase at high temperature by means of a process known as CVD (chemical vapour deposition) coating. By way of example, aluminide layers are produced by reacting a coating gas, such as, for example AlF (aluminium fluoride), at approximately 900-1100° C. with those surfaces of the components which are to be coated.

Box systems within which the components to be coated are mounted are in widespread use; coating gas (aluminium fluoride, AlF) is formed spatially separately above, next to and below the parts from a metallic donor material (e.g. AlCr, CoAl), an activator (e.g. AlF₃, NH₄F, initially crystalline at room temperature) and a process gas (e.g. Ar, H₂) at high temperatures. In what are known as retort furnaces, a plurality of boxes can be used simultaneously for coating purposes.

To coat inner surfaces of turbine blades or vanes, the coating gases have to be passed into the cavities inside the turbine blades or vanes by means of special pipelines and flow-admission devices, which represents a complex operation that is susceptible to faults, since the high process temperatures of 1100° C. cause sealing problems. Temperature gradients may likewise be highly problematical, since the active gases (e.g. AlF, AlCl) may condense on the cold line parts. Coating defects which are difficult to detect may occur both as a result of leaks and as a result of the gas breaking down prematurely.

This is where the invention comes in; one object is to create a process for effective, operationally reliable internal coating of gas turbine blades or vanes which avoids the abovementioned drawbacks.

This object is achieved, in conjunction with the generic features previously mentioned, by reducing pressure, which initially approximately corresponds to ambient pressure, at a coating temperature in the coating space by gas being sucked out, and refilling the coating space, during which the pressure rises approximately to ambient pressure, at least mainly with halide gas in order to immediately reform coating gas with the donor material.

Unlike in processes in widespread use for the internal coating of gas turbine blades or vanes, sufficient supply of coating gases to the internal surfaces is not effected by means of feed devices. Rather, the gas transport into the cavities of the blades or vanes which is required for effective coating of the inner walls is made possible by varying the pressure in the coating space. The loss of the gases which are active in coating caused by them being pumped out is counteracted by the fact that new coating gas is immediately generated again when the pressure rises. According to the invention, this is achieved by flooding the coating space with a halide gas (e.g. HF), which immediately forms new coating gas (AlF) with the donor material present in the coating space, during the pressure rise. The halide gas acts as an activator. The immediate reforming of coating gas allows the coating process to continue with full effect.

Preferred configurations of the process are reflected in the dependent claims. An internally coated gas turbine blade or vane produced by a process according to the invention is also claimed.

A process according to the invention ensures uniform internal coating of the gas turbine blades or vanes and eliminates gas supply systems which have hitherto been required and adapters which have hitherto been required for each one of the gas turbine blades or vanes to be coated. The coating takes place with a high quality despite the relatively simple and robust procedure.

Therefore, this also opens up a way of repairing turbine blades or vanes in order to coat their internal surfaces with a quality and efficiency which has not previously been enjoyed.

Of course, a process according to the invention is also suitable for coating the blades or vanes of industrial gas turbines.

In addition to alitizing using a suitable donor-activator combination, a process according to the invention is also suitable for application of further thermochemical layer systems, such as, for example, for chromizing, for boronizing, and for silicizing, and for combinations of these processes.

### DETAILED DESCRIPTION OF THE INVENTION

The gas turbine blades or vanes to be coated from the high-pressure turbine of an aircraft engine (produced from a single-crystal superalloy) are introduced into the box system of a coating installation in order to be coated; this coating installation is also suitable for operation under subatmospheric pressure and use of gaseous hydrogen fluoride (HF).

The donor used is AlCr, and the starting activator used is AlF₃. The process temperature is +1085° C. For pressure pulsing, the pressure in the coating space is reduced five times from approximately 1000 mbar to approximately 100 mbar, with the box system in each case being flooded with an H₂-HF gas mixture as the pressure rises again. The gas mixture flows directly onto the donor material.

As a result of the blade or vane inner surfaces being supplied with fresh coating gas (AlF) as the pressure rises, aluminide layers whose thickness is more than 35 μm are produced on the inner surfaces, while the outer layer thicknesses produced at the same time are 55 μm.

By locally covering the blade or vane outer surfaces, it is possible to deliberately prevent the formation of layers there.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

I claim:

1. A process for internally coating gas turbine blades or vanes, with or without simultaneous external coating, with protective diffusion layers by a CVD process in a coating space, which can be sealed off from the environment, at elevated temperature using at least one of an inert process gas and a reactive process gas, at least one halide as an activator, and at least one metallic material as donor, the activator and the donor being provided in the coating space in order to generate coating gas, the process comprising:
reducing pressure, which initially approximately corresponds to ambient pressure, at a coating temperature in the coating space by gas being sucked out, and
refilling the coating space, during which the pressure rises approximately to ambient pressure, at least mainly with halide gas in order to immediately reform coating gas with the donor material.

2. The process according to claim 1, wherein reduction of the pressure takes place repeatedly, and wherein the pressure is temporarily reduced from approximately 1000 mbar to 100 mbar or less.

3. The process according to claim 1, wherein the process is carried out in box systems within the coating space, and wherein gas-permeable boxes which hold the gas turbine blades or vanes including the activator and the donor material are arranged systematically.

4. The process according to claim 1, wherein the process is alitizing, chromizing, boronizing, silicizing, or combinations thereof.

5. The process according to claim 1, wherein cooling air admission openings are arranged so as to be open in roots of the gas turbine blades or vanes and accessible to the coating gas.

6. The process according to claim 2, wherein reduction of the pressure takes place three to six times.

7. The process according to claim 2, wherein the process is carried out in box systems within the coating space, and wherein gas-permeable boxes which hold the gas turbine blades or vanes including the activator and the donor material are arranged systematically.

8. The process according to claim 2, wherein the process is alitizing, chromizing, boronizing, silicizing, or combinations thereof.

9. The process according to claim 3, wherein the process is alitizing, chromizing, boronizing, silicizing, or combinations thereof.

10. The process according to claim 6, wherein the process is alitizing, chromizing, boronizing, silicizing, or combinations thereof.

11. The process according to claim 7, wherein the process is alitizing, chromizing, boronizing, silicizing, or combinations thereof.

12. The process according to claim 2, wherein cooling air admission openings are arranged so as to be open in roots of the gas turbine blades or vanes and accessible to the coating gas.

13. The process according to claim 3, wherein cooling air admission openings are arranged so as to be open in roots of the gas turbine blades or vanes and accessible to the coating gas.

14. The process according to claim 4, wherein cooling air admission openings are arranged so as to be open in roots of the gas turbine blades or vanes and accessible to the coating gas.

15. The process according to claim 6, wherein cooling air admission openings are arranged so as to be open in roots of the gas turbine blades or vanes and accessible to the coating gas.

16. The process according to claim 7, wherein cooling air admission openings are arranged so as to be open in roots of the gas turbine blades or vanes and accessible to the coating gas.

17. The process according to claim 8, wherein cooling air admission openings are arranged so as to be open in roots of the gas turbine blades or vanes and accessible to the coating gas.

18. The process according to claim 9, wherein cooling air admission openings are arranged so as to be open in roots of the gas turbine blades or vanes and accessible to the coating gas.

19. The process according to claim 10, wherein cooling air admission openings are arranged so as to be open in roots of the gas turbine blades or vanes and accessible to the coating gas.

20. The process according to claim 11, wherein cooling air admission openings are arranged so as to be open in roots of the gas turbine blades or vanes and accessible to the coating gas.

21. An internally coated gas turbine blade or vane produced by the process of claim 1.
